(19) United States
(12) Patent Application Publication
(10) Pub. No.: US 2004/0044938 A1
(43) Pub. Date: Mar. 4, 2004

(54) System for testing different types of semiconductor devices in parallel at the same time

(75) Inventor: Kyoung-Il Heo, Chungcheongnam-do (KR)

Correspondence Address: MARGER JOHNSON & McCOLLOM, P.C., 1030 S. W. Morrison Street, Portland, OR, 97205, US

(73) Assignee: Samsung Electronics Co., Ltd., Suwon-City (KR)

(21) Appl. No.: 10/404,984

(22) Filed: Mar. 31, 2003

(30) Foreign Application Priority Data
Aug. 14, 2002 (KR) 2002-48043

(51) Int. Cl. G06F 11/00; G01R 31/28

(52) U.S. Cl. 714/738

(57) ABSTRACT

Disclosed is a semiconductor test system which includes a plurality of test stations, a plurality of test pattern generators corresponding to the test stations and a plurality of comparators corresponding to the test stations. Semiconductor devices under test are mounted on each of the plurality of test stations. Each of the test pattern generators generates test patterns and expected data in response to a test command from a host. Each of the comparators compares data from semiconductor devices on a corresponding test station with the expected data. In particular, semiconductor devices on at least one of the test stations may be of different type from those on each of remaining test stations. The semiconductor test system is capable of testing semiconductor devices on the test stations in parallel at the same. This test scheme allows for decrease in the time and cost that are needed to test different types of semiconductor devices.

This application relies from priority upon Korean Patent Application No. 2002-48043, filed on Aug. 14, 2002, the contents of which are herein incorporated by reference in their entirety.

### FIELD OF THE INVENTION

The present invention is related to a system for testing semiconductor devices, and more particular to a system for testing a plurality of semiconductor devices in parallel at the same time.

### BACKGROUND OF THE INVENTION

In testing a semiconductor device by a semiconductor test system, the semiconductor test system provides test signals to the semiconductor device under test and compares the resulting output of the device under test with expected data to determine whether the semiconductor device works correctly or not. Since the modern semiconductor device, such as an LSI (large scale integrated circuit), has a large number of input/output pins, a semiconductor test system also has a large number of test channels corresponding to the pins of the semiconductor device to be tested.

Typically, a semiconductor test system has a large number of test channels corresponding to a large number of pins on a single semiconductor device. On the other hand, a plurality of devices each having a smaller number of pins may be tested in parallel by such a semiconductor test system, without increasing a system input/output (I/O) interconnect and/or bandwidth requirements. Accordingly, it is advantageous to divide the test channels to form a plurality of test stations to test a plurality of semiconductor devices at the same time to increase the test efficiency. In testing a plurality of IC devices at the same time by a plurality of test stations connected to a simple test system, the timings of the test signals among the various stations must be the same, i.e., system-wide timing differences between the test stations must be adjusted to be zero.

One example for realizing a zero timing error between test stations is disclosed in U.S. Pat. No. 6,263,463 entitled “TIMING ADJUSTMENT CIRCUIT FOR SEMICONDUCTOR TEST SYSTEM”. The cited reference has disclosed a technique for testing the same type of semiconductor devices in parallel at the same time. However, since only one type of semiconductor devices are simultaneously tested in parallel through one test system, testing of different types of semiconductor devices requires further development.

### SUMMARY OF THE INVENTION

It is therefore an object of the invention to provide a test system capable of testing different types of semiconductor devices in parallel at the same time.

In accordance with one aspect of the present invention, there is provided a single semiconductor test system which nevertheless includes a plurality of test stations. A plurality of semiconductor devices under test are mounted on each of the plurality of test stations. A plurality of test pattern generators correspond to the test stations, respectively. Each of the test pattern generators generates test patterns and expected data in response to a test command from a host. A plurality of comparators correspond to the test stations. Each of the comparators compares data from semiconductor devices on a corresponding test station with expected data from a corresponding test pattern generator. Semiconductor devices on at least one of the test stations are different in type from those on at least another of the remaining test stations.

In this preferred embodiment, each of the test pattern generators includes a pattern generator for responding to the test command and generating a test pattern and the expected data, the test pattern being supplied to semiconductor devices on a corresponding test station; a timing generator for generating timing signals indicating a point of time when the test pattern from the pattern generator is transferred to the semiconductor devices on a corresponding test station; and a formatter for providing the test pattern from the pattern generator to the semiconductor devices on the corresponding test station in synchronization with the timing signals.

In this preferred embodiment, each of the test stations includes a plurality of pin cards for transferring a test pattern from a corresponding pattern generator to input/output pins of corresponding semiconductor devices.

### BRIEF DESCRIPTION OF THE DRAWINGS

A more complete appreciation of the present invention, and many of the attendant advantages thereof, will become readily apparent as the same becomes better understood by reference to the following detailed description when considered in conjunction with the accompanying drawings in which like reference symbols indicate the same or similar components, wherein:

FIG. 1 is a block diagram of a semiconductor test system according to the present invention; and

FIG. 2 is a flowchart for describing an operation of a semiconductor test system in FIG. 1 when a host processor generates a test command.

### DESCRIPTION OF THE PREFERRED EMBODIMENT

The preferred embodiment of the invention will be more fully described with reference to the attached drawings.

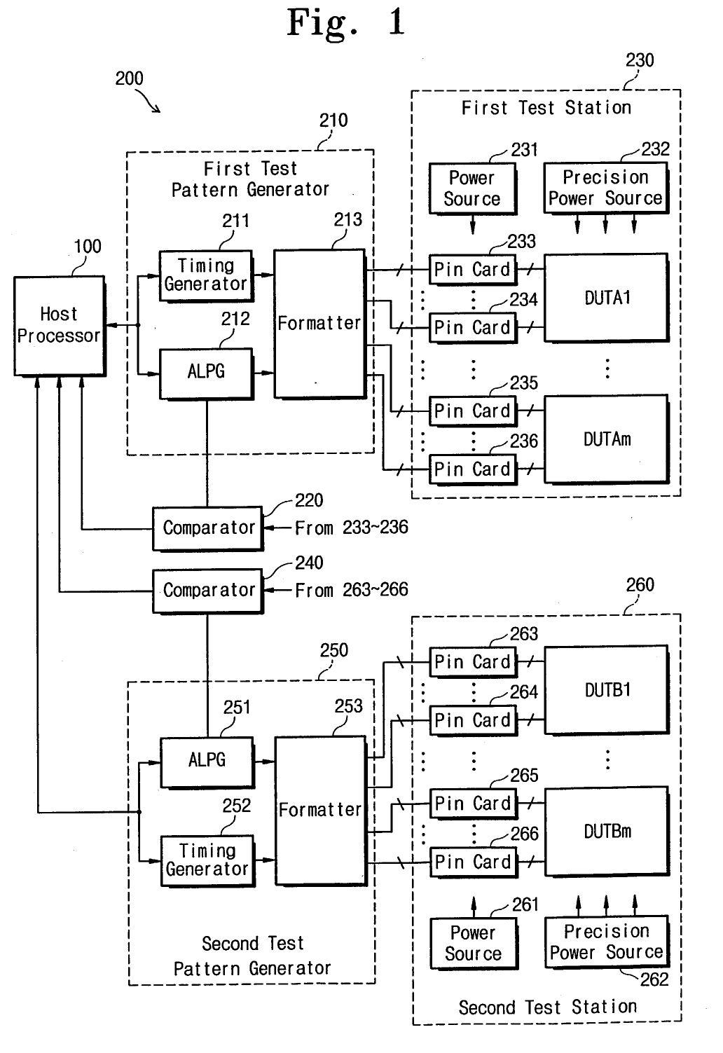

FIG. 1 is a block diagram showing a structure of the present semiconductor test system for testing a plurality of semiconductor devices in parallel at the same time by a plurality of test stations. For convenience of explanation, the example of FIG. 1 is to test semiconductor devices arranged on two test stations, although those of skill in the art will appreciate that any number of test stations can be used. A semiconductor test system 200 according to the present invention includes the first and second test pattern generators 210 and 250, comparators 220 and 240, and the first and second test stations 230 and 260. A plurality of, for example, m semiconductor devices under test DUTA1-DUTAm are arranged on the first test station 230, and a plurality of, for example, m semiconductor devices under test DUTB1-DUTBm are arranged on the second test station 260.

The first test pattern generator 210 provides the semiconductor devices DUTA/DUTAm on the first test station 230 with test patterns in response to a test command from a host processor 100. The first test pattern generator 210 incorporates a timing generator 211, an arithmetic logic pattern generator (abbreviated “ALPG” in the figure) 212 and a formatter 213.

The arithmetic logic pattern generator 212 generates a test pattern and expected data in response to a test command from the host processor 100. The test pattern is provided to the formatter 213, and the expected data is provided to the comparator 220. The timing generator 211 outputs timing signals indicating a point of time when the test pattern generated from the arithmetic logic pattern generator 212 is transferred to the first test station 230. The timing signals are provided to the formatter 213. The formatter 213 provides the test pattern from the arithmetic logic pattern generator 212 to the first test station 230 in synchronization with the timing signals from the timing generator 211.

The first test station 230 has pin cards 233-236 coupled with input/output pins of the semiconductor devices DUTA1-DUTAm. The pin cards 233-234 are connected with pins of the semiconductor device DUTA1, and the pin cards 235-236 are connected with pins of the semiconductor device DUTAm. The pin cards 233-236 receive and amplify test patterns from the formatter 213 in the first test pattern generator 210, and transfer amplified test patterns to corresponding semiconductor devices. The first test station 230 further comprises a power source 231 and a precision power source 232. The power source 231 supplies a power supply voltage to the pin cards 233-236. The precision power source 232 supplies various sorts of precise power supply voltages to the semiconductor devices DUTA1-DUTAm through corresponding pins.

Data from the semiconductor devices DUTA1-DUTAm are transferred to the comparator 220 through the pin cards 233-236. The comparator 220 compares received data from each semiconductor device with expected data from the arithmetic logic pattern generator 212, and supplies resulting data to the host processor 100. Although not shown in the figure, the comparator 220 may be formed of comparison units corresponding to the semiconductor devices DUTA1-DUTAm, respectively. If received data from a semiconductor device in the first test station is equal to the expected data, the semiconductor device is considered as a normal or good chip. On the other hand, if received data from a semiconductor device in the first test station is not equal to the expected data, the semiconductor device is considered as a bad chip.

Meanwhile, the second test pattern generator 250 provides test patterns to semiconductor devices DUTB1-DUTBm on the second test station 260 in response to a test command from the host processor 100. The second test pattern generator 250 includes an arithmetic logic pattern generator (abbreviated “ALPG” in the figure) 251, a timing generator 252, and a formatter 253.

The arithmetic logic pattern generator 251 generates a test pattern and expected data in response to the test command from the host processor 100. The test pattern is supplied to the formatter 253, and the expected data is provided to a comparator 240. The timing generator 252 outputs timing signals indicating a point of time when the test pattern generated from the arithmetic logic pattern generator 251 is transferred to the second test station 260. The timing signals are provided to the formatter 253. The formatter 253 provides the test pattern from the arithmetic logic pattern generator 251 to the second test station 260 in synchronization with the timing signals from the timing generator 252.

The second test station 260 has pin cards 263-266 coupled with input/output pins of the semiconductor devices DUTB1-DUTBm. The pin cards 263-264 are connected with pins of the semiconductor device DUTB1, and the pin cards 265-266 are connected with pins of the semiconductor device DUTBm. The pin cards 263-266 receive and amplify test patterns from the formatter 253 in the second test pattern generator 250, and transfer amplified test patterns to corresponding semiconductor devices. The second test station 260 further comprises a power source 261 and a precision power source 262. The power source 261 supplies a power supply voltage to the pin cards 263-266. The precision power source 262 supplies various sorts of precise power supply voltages to the semiconductor devices DUTB1-DUTBm through corresponding pins.

Data from the semiconductor devices DUTB1-DUTBm is transferred to the comparator 240 through the pin cards 263-266. The comparator 240 compares received data from each semiconductor device with expected data from the arithmetic logic pattern generator 251, and supplies resulting data to the host processor 100. Although not shown in the drawing, the comparator 240 may be formed of comparison units corresponding to the semiconductor devices DUTB1-DUTBm. If received data from a semiconductor device in the first test station is equal to the expected data, the semiconductor device is considered as a normal or good chip. On the other hand, if received data from a semiconductor device in the first test station is not equal to the expected data, the semiconductor device is considered as a bad chip.

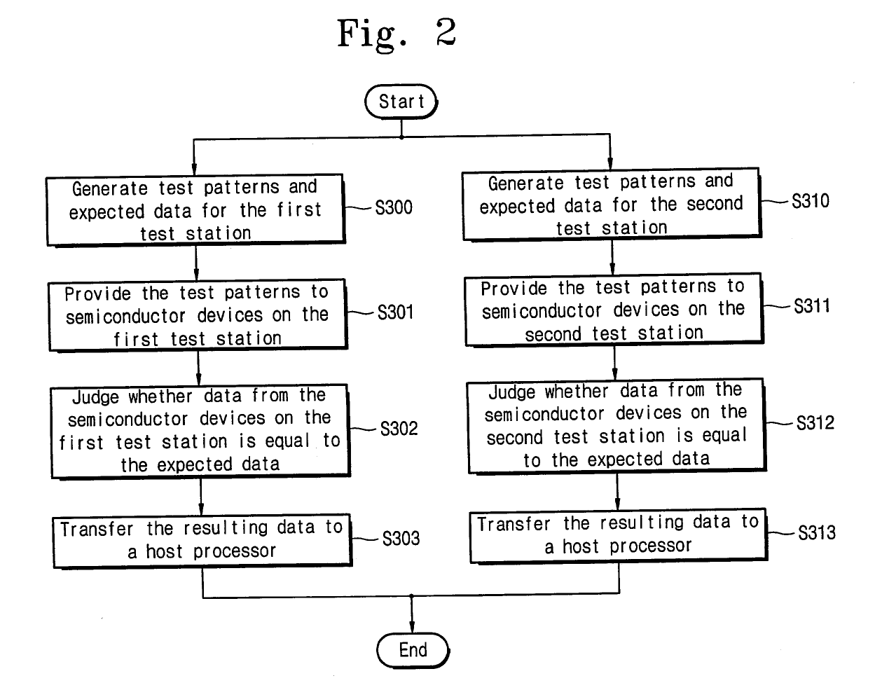

FIG. 2 is a flowchart for describing an operation of a semiconductor test system in FIG. 1 when a host processor generates a test command.

Now, an operation of the present semiconductor test system will be described with reference to FIGS. 1 and 2.

In a step S300, the first test pattern generator 210 generates a test pattern and expected data for the first test station 230. Likewise, in a step S310, the second test pattern generator 250 generates a test pattern and expected data for the second test station 260.

In a next step S301, the first test pattern generator 210 provides the test pattern to semiconductor devices DUTA1-DUTAm on the first test station 230. Likewise, in a step S311, the second test pattern generator 250 provides the test pattern to semiconductor devices DUTB1-DUTBm on the second test station 260.

A comparator 220 receives data from the semiconductor devices DUTA1-DUTAm of the first test station through pin cards 233-236, and compares received data from each semiconductor device with the expected data. This is carried out in a step S302. Likewise, in a step S312, a comparator 240 receives data from the semiconductor devices DUTB1-DUTBm of the first test station through pin cards 263-266, and compares received data from each semiconductor device with the expected data.

In a step S303, the comparator 220 transfers resulting data to the host processor 100. In a step S313, the comparator 240 transfers resulting data to the host processor 100. As understood from the FIG. 2, the procedures S300-S303 for testing semiconductor devices DUTA1-DUTAm on the first test station 230 are carried out in parallel at the same time together with the procedures S3110-S313 for testing semiconductor devices DUTB1-DUTBm on the second test station 260. After a first type of semiconductor devices DUTA1-DUTAm are arranged on the first test station 230 and a second type of semiconductor devices DUTB1-DUTBm are arranged on the second test station 260, the present semiconductor test system 200 tests the semiconductor devices DUTA1-DUTAm and DUTB1-DUTBm in parallel at the same time. This test scheme allows for a proportional decrease in the time and cost that are needed to test different types of semiconductor devices.

There is disclosed only one example to test two types or sorts of semiconductor devices using two test stations, but it is obvious that the number of test stations may be variously modified to test three or more types of semiconductor devices in parallel at the same time. Also, it is obvious that semiconductor devices of the same type can be arranged on test stations. The number of semiconductor devices under test and the number of pins of each DUT can be modified variously.

The invention has been described using exemplary preferred embodiments. However, it is to be understood that the scope of the invention is not limited to the disclosed embodiment. On the contrary, it is intended to cover various modifications and similar arrangements. The scope of the claims, therefore, should be accorded the broadest interpretation so as to encompass all such modifications and similar arrangements.

What is claimed is:

1. A semiconductor test system comprising:
a plurality of test stations, wherein a plurality of semiconductor devices under test are mounted on each of the plurality of test stations;
a plurality of test pattern generators corresponding to the test stations, wherein each of the test pattern generators generates test patterns and expected data in response to a test command from a host; and
a plurality of comparators corresponding to the test stations, wherein each of the comparators compares data from semiconductor devices on a corresponding test station with the expected data from a corresponding one of the test pattern generators,
wherein semiconductor devices on at least one of the test stations are different in type from those on at least another of the remaining test stations.

2. The semiconductor test system according to claim 1, wherein each of the test pattern generators includes:
a pattern generator for responding to the test command and generating a test pattern and the expected data, the test pattern being supplied to semiconductor devices on a corresponding test station;
a timing generator for generating timing signals indicating a point of time when the test pattern from the pattern generator is transferred to the semiconductor devices on a corresponding test station; and
a formatter for providing the test pattern from the pattern generator to the semiconductor devices on the corresponding test station in synchronization with the timing signals.

3. The semiconductor test system according to claim 2, wherein each of the test stations includes a plurality of pin cards for transferring a test pattern from a corresponding pattern generator to input/output pins of corresponding semiconductor devices.

4. A semiconductor test system comprising:
a first test station configured for testing a plurality of first semiconductor devices;
a first test pattern generator for responding to a test command from a host and generating test patterns and expected data, the test patterns being routed for testing of the first semiconductor devices;
a first comparator for comparing data receivable from the first semiconductor devices with the expected data from the first test pattern generator;
a second test station configured for testing a plurality of second semiconductor devices;
a second test pattern generator for responding to the test command and generating test patterns and expected data, the test patterns being routed for testing of the plurality of second semiconductor devices; and
a second comparator for comparing data receivable from the plurality of second semiconductor devices with the expected data from the second test pattern generator,
wherein the first test station is configured for semiconductor devices different in type from that of the second semiconductor devices for which the second test station is configured.

5. The semiconductor test system according to claim 4, wherein the first test pattern generator includes:
a pattern generator for responding to the test command and generating a test pattern and the expected data, the test pattern being routed for testing of the first semiconductor devices;
a timing generator for generating timing signals indicating a point of time when the test pattern from the pattern generator is routed for testing of the first semiconductor devices; and
a formatter for routing the test pattern from the pattern generator for testing of the first semiconductor devices in synchronization with the timing signals.

6. The semiconductor test system according to claim 4, wherein the first test station includes a plurality of first pin cards which correspond to input/output pins of each of the first semiconductor devices, the first test station transferring the test patterns from the first test pattern generator to the plurality of first pin cards.

7. The semiconductor test system according to claim 4, wherein the second test pattern generator includes:
a pattern generator for responding to the test command and generating a test pattern and the expected data, the test pattern being routed for testing of the second semiconductor devices;
a timing generator for generating timing signals indicating a point of time when the test pattern from the pattern generator is routed for testing of the second semiconductor devices; and
a formatter for routing the test pattern from the pattern generator for testing of the second semiconductor devices in synchronization with the timing signals.

8. The semiconductor test system according to claim 4, wherein the second test station includes a second plurality of pin cards which correspond to input/output pins of each of the second semiconductor devices, the second test station transferring the test patterns from the first test pattern generator to the plurality of second pin cards.
